(19) United States
(12) Patent Application Publication
(10) Pub. No.: US 2025/0336452 A1
(43) Pub. Date: Oct. 30, 2025

(54) APPARATUS WITH POST-PROCESSING DATA ADJUSTMENT MECHANISM AND METHODS FOR OPERATING THE SAME

(71) Applicant: Micron Technology, Inc., Boise, ID (US)

(72) Inventors: Caixia Yang, Boise, ID (US); Deping He, Boise, ID (US); Chun Sum Yeung, San Jose, CA (US)

(21) Appl. No.: 19/094,008

(22) Filed: Mar. 28, 2025

Related U.S. Application Data
(60) Provisional application No. 63/640,477, filed on Apr. 30, 2024.

(51) Int. Cl. G11C 16/34

(52) U.S. Cl. CPC G11C 16/3431; G11C 16/349

(57) ABSTRACT

Methods, apparatuses and systems related to managing stored data in view of charge losses are described. An apparatus may include a management mechanism that scans memory cells and adjusts read voltage levels for the memory cells to account for charge losses during operation of the apparatus. The apparatus may further leverage the management mechanism to detect or estimate one or more targeted conditions by tracking an adjustment progress while implementing the management mechanism. When the adjustment progress reaches a predetermined condition, the apparatus can estimate the occurrence of the one or more targeted conditions and implement a data refresh mechanism to restore the charges to their intended levels instead of completing the management mechanism.

### CROSS-REFERENCE TO RELATED APPLICATION(S)

The present application claims priority to U.S. Provisional Patent Application No. 63/640,477, filed Apr. 30, 2024, the disclosure of which is incorporated herein by reference in its entirety.

### TECHNICAL FIELD

The disclosed embodiments relate to devices, and, in particular, to semiconductor memory devices with post-processing data adjustment mechanisms and methods for operating the same.

### BACKGROUND

Memory systems can employ memory devices to store and access information. The memory devices can include volatile memory devices, non-volatile memory devices (e.g., flash memory employing “NAND” technology or logic gates, “NOR” technology or logic gates, or a combination thereof), or a combination device. The memory devices utilize electrical energy, along with corresponding threshold levels or processing/reading voltage levels, to store and access data. However, the stored energy is vulnerable to a variety of factors, such as environmental temperatures, storage duration, unpowered or unoperated duration, or the like. The vulnerabilities can lead to data loss, which can cause performance issues, such as degraded access time, data loss, and/or catastrophic device failure.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure.

FIG. 1 is a block diagram of a computing system in accordance with an embodiment of the present technology.

FIG. 2A and FIG. 2B illustrate manufacturing steps in accordance with an embodiment of the present technology.

FIG. 3 illustrates voltage shifts that may occur in storage devices.

FIG. 4 illustrates example adjustments to account for the voltage shifts in accordance with an embodiment of the present technology.

FIG. 5 is a flow diagram illustrating an example method of operating an apparatus to adjust for the voltage shifts in accordance with an embodiment of the present technology.

FIG. 6 is a flow diagram illustrating an example method of manufacturing/operating an apparatus to adapt the adjustment in initializing the apparatus in accordance with an embodiment of the present technology.

FIG. 7 is a schematic view of a system that includes an apparatus in accordance with an embodiment of the present technology.

### DETAILED DESCRIPTION

As described in greater detail below, the technology disclosed herein relates to an apparatus, such as memory systems, systems with memory devices, related methods, etc., for adjusting data access/management operations to account for voltage shifts and for adapting such adjustments for device initialization, reset, and the like. For example, the apparatus (e.g., a non-volatile memory device within a personal computing device, such as a mobile phone) can estimate charge loss corresponding to the stored data according to a tracked duration since the previous/last power application. Based on the tracked duration, the apparatus can implement a data management mechanism (e.g., a background scan for estimating charge loss) or a portion thereof to manage the stored data.

The data management mechanism can be configured or targeted for deployed operation of the device. In some embodiments, the data management mechanism can include implementing background scans and/or tracking durations since previous/last power-on. Based on the resulting scan and/or tracked duration, the apparatus can assign (e.g., via pointers) groupings of memories (e.g., memory blocks or other related groupings) to bins or other similar loss-estimate groupings. The apparatus can use the bin assignments to adjust one or more data access or data maintenance processes, such as by adjusting read level voltages and/or by triggering data refresh or error recovery. For embodiments of the present technology, the apparatus can further utilize the data management mechanism for managing previously loaded data under targeted conditions, such as first-power-up events, device/system reset events, a power-up event following a long time (as defined by a predetermined thresholding conditions/parameters) without having power, and/or the like.

As an illustrative example, the apparatus can include non-volatile memory devices (e.g., NAND memory devices) within electronic devices, such as smart phones or other consumer products, used to store preloaded software or operating instructions. However, the electronic devices may remain at the retail store or warehouse over an unpredictable duration before users buy and powers up the devices. Accordingly, the memory devices can remain unpowered for potentially long periods, which can negatively affect the preloaded data.

Such potential negative impact on the preloaded data may be worsened by manufacturing steps that precede the unpredictable duration. For example, electronic device manufactures may attach or mount the memory devices to substrates and/or apply protective structures (e.g., underfills) after preloading data. However, such manufacturing processes often require external conditions, such as elevated ambient/device temperatures, that negatively affect (e.g., by causing charge loss or increasing the rate thereof) the integrity of the preloaded data.

Often, the preloaded data can include mission critical data, such as an image of the operating system (OS). In order to prevent or minimize corruption of such preloaded data, the memory device can include a data management or adjustment mechanism configured to account for the affected integrity of the data. In some embodiments, the memory device can have a post-underfill bootup (e.g., initial device power up after completion of manufacturing) that includes the data management mechanism. Such data management mechanism can include leveraging (e.g., enabling or forcing) a Write Booster feature of the Universal Flash Storage (UFS) standard, forcing single-level cell (SLC) writes, or the like before the underfill step. However, such remedial measures often require additional steps, increase resource usages, delays, or other types of costs. For example, leveraging the Write Booster features before the underfill step can violate UFS protocol, thereby requiring the electronic device manufacturer/assembler to take additional steps that account for such violation. Also, forced SLC writes can impact the performance of the initial or immediately subsequent power-on event since the SLC mode significantly reduces the number of write-available blocks.

As described in further detail below, embodiments of the technology described herein can use or adapt the data management mechanism to account for the negative effects of prolonged removal of power, manufacturing conditions, etc. on the preloaded data. For example, the memory device can include an adapted management mechanism that can selectively implement a background scan and a bin assignment of the data management mechanism. The adapted management mechanism can be configured to iteratively (1) scan/sample charge levels or read error rates of memory groupings using the background scan and (2) adjust the bin assignments of the memory groupings according to the scan results. The bin assignments can correspond to (1) an estimated charge loss for the corresponding memory grouping and (2) a processing adjustment, such as a read level offset, that accounts for the estimated charge loss.

In iteratively scanning and adjusting, the adapted management mechanism can be configured to track an adjustment progress that effectively represents a degree or a severity of the charge loss. Some examples of the adjustment progress can include a program-erase count, a number of adjusted groupings, a magnitude of the bin adjustment, or a combination thereof. The adapted management mechanism can be configured to stop the scan and adjustment, thereby deviating from the data management mechanism as intended for the standard operation, and implement a data refresh operation without completing the scan of the intended set of groupings.

As such, the adapted management mechanism can account for potential corruption of preloaded data using standard operating features instead of specifically targeted (e.g., rarely used) features. Moreover, the adapted management mechanism can implement such data management while complying with UFS protocol. Further, the adapted management mechanism can reduce the duration of the data management, such as by recognizing extreme charge loss conditions using the adjustment progress and then implementing the data refresh mechanism without completing the background scan. Additionally, the adapted management mechanism can improve the performance by removing the forced SLC write requirement and allowing other denser writes before the underfill process.

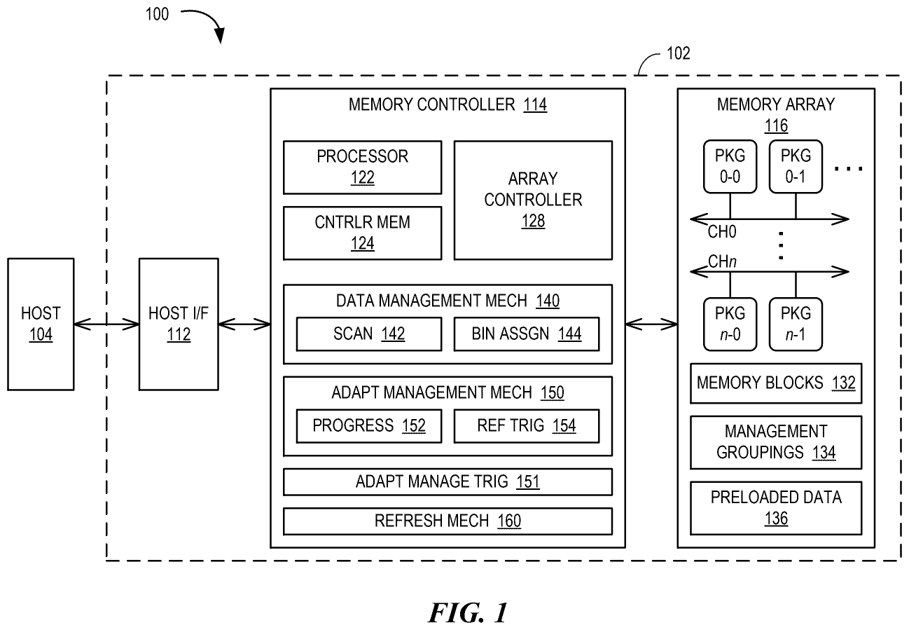

FIG. 1 is a block diagram of a computing system 100 in accordance with an embodiment of the present technology. The computing system 100 can include a personal computing device/system, a mobile device (e.g., a mobile/smart phone), a wearable device, or the like. The computing system 100 can include a memory system or subsystem 102 coupled to a host device 104. The host device 104 can include one or more processors that can write data to and/or read data from the memory system 102. For example, the host device 104 can include a central processing unit (CPU) controlling the operation of the computing system 100.

The memory system 102 can include circuitry configured to store data (via, e.g., write operations) and provide access to stored data (via, e.g., read operations). For example, the memory system 102 can include a persistent or non-volatile data storage system, such as a NAND-based Flash drive system or the like. In some embodiments, the memory system 102 can include a host interface 112 (e.g., buffers, transmitters, receivers, and/or the like) configured to facilitate communications with the host device 104. For example, the host interface 112 can be configured to support one or more host interconnect schemes, such as Universal Serial Bus (USB), Peripheral Component Interconnect (PCI), Serial AT Attachment (SATA), USF, or the like. The host interface 112 can receive commands, addresses, data (e.g., write data), and/or other information from the host device 104. The host interface 112 can also send data (e.g., read data) and/or other information to the host device 104.

The memory system 102 can further include a memory controller 114 and a memory array 116. The memory array 116 can include memory cells that are configured to store a unit of information. The memory controller 114 can be configured to control the overall operation of the memory system 102, including the operations of the memory array 116.

In some embodiments, the memory array 116 can include a set of storage devices or packages. Each of the storage devices can include a set of memory cells that each store data in a charge storage structure. The memory cells can include, for example, floating gate, charge trap, phase change, ferroelectric, magnetoresistive, and/or other suitable storage elements configured to store data persistently or semi-persistently. The memory cells can be one-transistor memory cells that can be programmed to a target state to represent information. For instance, electric charge can be placed on, or removed from, the charge storage structure (e.g., the charge trap or the floating gate) of the memory cell to program the cell to a particular data state. The stored charge on the charge storage structure of the memory cell can indicate a Vt of the cell. For example, a SLC can be programmed to a targeted one of two different data states, which can be represented by the binary units 1 or 0. Also, some flash memory cells can be programmed to a targeted one of more than two data states. Multi-level cells (MLCs) may be programmed to any one of four data states (e.g., represented by the binary 00, 01, 10, 11) to store two bits of data. Similarly, triple-level cells (TLCs) may be programmed to one of eight (i.e., 13) data states to store three bits of data, and quadruple-level cells (QLCs) may be programmed to one of 16 (i.e., 14) data states to store four bits of data.

Such memory cells may be arranged in rows (e.g., each corresponding to a word line 130) and columns (e.g., each corresponding to a bit line). The arrangements can further correspond to different groupings for the memory cells. For example, each word line 130 can correspond to one or more memory pages. Also, the memory array 116 can include memory blocks 132 that each include a set of memory pages. In operation, the data can be written or otherwise programmed (e.g., erased) with regards to the various memory regions of the memory array 116, such as by writing to groups of pages and/or memory blocks 132. In NAND-based memory, a write operation often includes programming the memory cells in selected memory pages with specific data values (e.g., a string of data bits having a value of either logic 0 or logic 1). An erase operation is similar to a write operation, except that the erase operation re-programs an entire memory block or multiple memory blocks to the same data state (e.g., logic 0).

In some embodiments, the memory system 102 can further group the memory cells (e.g., the memory blocks 132) into data management groupings 134 for the purposes of managing the data stored therein. The data management groupings 134 can correspond to one of many different granularities, containing only whole codewords, whole pages, whole super pages, or whole superblocks, or a combination thereof. For example, the data management groupings 134 can be based on superblocks that each include a set of data blocks spanning multiple dies/packages that are written in an interleaved fashion. Further the data management groupings 134 can include block families that each include memory cells that have been programmed within a specific time window. As such, the memory system 102 can use the data management groupings 134 that include blocks and/or superblocks that are expected to exhibit similar or correlated charge retention states or other data metrics. Details regarding the data management and the use of data management groupings 134 are further described below.

The memory system 102 can include preloaded data 136 in the memory array 116. The preloaded data 136 can include data stored on the computing system 100 prior to deployment/usage thereof. In some embodiments, the preloaded data 136 can be loaded onto the memory array 116 before one or more manufacturing steps, such as attaching the memory array 116 (e.g., the corresponding packages/dies) to a substrate, applying/flowing underfill, and/or the like. In some applications, the preloaded data 136 can include instructions or software for operating the computing system 100. For example, the preloaded data 136 can correspond to the operating system or an image thereof for the computing system 100.

While the memory array 116 is described with respect to the memory cells, it is understood that the memory array 116 can include other components (not shown). For example, the memory array 116 can also include other circuit components, such as multiplexers, decoders, buffers, read/write drivers, address registers, data out/data in registers, etc., for accessing and/or programming (e.g., writing) the data and for other functionalities.

As described above, the memory controller 114 can be configured to control the operations of the memory array 116. The memory controller 114 can include a processor 122, such as a microcontroller, special purpose logic circuitry (e.g., a field programmable gate array (FPGA), an application specific integrated circuit (ASIC), etc.), or other suitable processor. The processor 122 can execute instructions encoded in hardware, firmware, and/or software (e.g., instructions stored in controller-embedded memory 124) to execute various processes, logic flows, and routines for controlling operation of the memory system 102 and/or the memory array 116.

Further, the memory controller 114 can further include an array controller 128 that controls or oversees detailed or targeted aspects of operating the memory array 116. For example, the array controller 128 can provide a communication interface between the processor 122 and the memory array 116 (e.g., the components therein). The array controller 128 can function as a multiplexer/demultiplexer, such as for handling transport of data along serial connection to flash devices in the memory array 116.

In addition to storing and accessing data in the memory array 116, the memory controller 114, logic circuits within the memory array 116, corresponding firmware, or a combination thereof can manage the data stored in the memory array 116. For example, the memory system 102 can include a data management mechanism 140 (e.g., software, firmware, dedicated logic/circuit, or a combination thereof) configured to update one or more operating parameters to account for charge loss. The data management mechanism 140 can be configured to track charge loss, shift, or other disturbances within the memory array 116 (e.g., according to the data management groupings 134) and adjust and calibrate the operating parameters. In effect, the data management mechanism 140 can use the tracked measures and the adjustments to allow the stored data to be accessed with acceptable (e.g., according to a predetermined threshold) Bit Error Rate (BER). Thus, the data management mechanism 140 can increase the duration between data refresh operations and the refresh rate by allowing acceptable access to otherwise disturbed data/charge levels.

In some embodiments, the data management mechanism 140 can be configured to implement a background scan 142 that evaluates the stored charge levels. The memory system 102 can implement the background scan 142 according to the memory blocks 132 and/or the data management groupings 134 (e.g., block families or superblocks). For example, the memory system 102 can read a portion of each superblock using a previously established read level and compute the corresponding error rate. When the error rate exceeds a predetermined threshold, the memory system 102 can estimate that a qualifying amount of charge has been lost and adjust the read level as a remedial response.

The management mechanism 140 can represent the charge loss and the read level adjustment using bin assignments 144. In other words, the memory system 102 can assign each block or data management grouping to a bin that uniquely corresponds to a read offset level. As the stored data gets older and more charge is lost, the memory system 102 can sequentially assign the block/grouping to the next bin. The memory system 102 can refresh the blocks/groupings in the last bin.

As an illustrative example, newly written blocks can be assigned to Bin 0, which can correspond to a highest read level voltage setting (e.g., highest positive offset for a low base level voltage or zero offset for a high base level voltage). When the result of the background scan 142 (e.g., BER) exceeds a predetermined acceptability threshold, the memory system 102 can assign the corresponding block/grouping to the next bin, such as Bin 1, that corresponds to a reduced read level voltage (e.g., second highest positive offset for the low base level scheme or a first negative offset for a high base level scheme). Accordingly, the memory system 102 can change the bin assignment 144 for the corresponding block(s)/group. In some embodiments, the bin assignments 144 can be implemented using pointers that each correspond to a unique grouping and point to the assigned read levels or corresponding offset values.

In addition to the data management mechanism 140, the memory system 102 can include an adapted management mechanism 150 that leverages the data management mechanism 140 to manage the stored data in targeted scenarios, such as an initial power on event (e.g., after deployment or by a consumer), a first power on event following completion of manufacturing/assembly, a first power on event following a factory reset, a power on event after a prolonged duration without power, and the like. Accordingly, the adapted management mechanism 150 can be configured to selectively implement iterate through the data management mechanism 140 until a predetermined condition is satisfied. Once the predetermined condition is met, the adapted management mechanism 150 can implement a data refresh mechanism 160 that rewrites the affected data and restores the stored charges to the targeted levels.

In some embodiments, the memory system 102 can trigger or implement the adapted management mechanism 150 according to an adapted management trigger 151. The adapted management trigger 151 can include a tracked data, such as a status parameter, a measure, or the like indicative of targeted conditions, such as the initial power on event, the first power on event following completion of manufacturing/assembly, the first power on event following a factory reset, the power on event after a prolonged duration without power, etc.

For example, the adapted management trigger 151 can include a status bit that is preset to a value at the end of manufacturing, after a factory reset, or the like. Accordingly, the memory system 102 can be configured to check the status bit during a power on process and implement the adapted management trigger 151 for the targeted conditions. After implementing the adapted management trigger 151, the memory system 102 can change the value of the status bit.

Additionally or alternatively, the memory system 102 can track the adapted management trigger 151by measuring or estimating a power removal duration (e.g., following power off, removal of battery, or when battery charge levels fall below a triggering threshold). As examples, the memory system 102 can measure or estimate the power removal duration by using internally stored power to operate a counter or by charging a capacitor during runtime and assessing the remaining charges when power becomes available. When the adapted management trigger 151 exceeds a predetermined threshold indicative of a substantial charge loss or a potential data disturbance, the memory system 102 can adapted management mechanism 150. In other embodiments, the memory system 102 can implement the adapted management mechanism 150 during each power up event.

The memory system 102 can be configured to use the adapted management mechanism 150 to assess and manage the stored data, such as the preloaded data 136, that experienced the targeted conditions. For example, the adapted management mechanism 150 can be configured to manage or maintain the operating system or the image thereof in the memory array 116 across manufacturing conditions (e.g., elevated temperatures during solder reflow or underfill application) and/or prolonged storage duration, such as between completion of manufacturing and first power up event by a consumer following the purchase of the computing system 100 (e.g., fresh out of box or FoB condition).

In managing such data, the adapted management mechanism 150 can be configured to selectively leverage and implement the data management mechanism 140. For example, the adapted management mechanism 150 can implement the background scan 142 and iteratively assess and process data stored in the data management groupings 134 (e.g., super blocks or block families). During the iterative process, the memory system 102 (e.g., the memory controller 114) can compute and track an adjustment progress 152. The adjustment progress 152 can include a quantifiable measure that can be used to estimate targeted conditions (e.g., the FoB condition) that require implementation of the data refresh mechanism 160. For example, the adjustment progress 152 can include a program erase count (PEC).

For the selective aspect, the adapted management mechanism 150 can be configured to stop the background scan 142 (e.g., break the iteration without completing/assessing the remaining groupings) and implement the data refresh mechanism 160 when the adjustment progress 152 satisfies a refresh trigger condition 154. Continuing with the PEC example, the refresh trigger condition 154 can include a predetermined threshold PEC (e.g., 5, 10, 12, 15, or another positive integer). Accordingly, the memory system 102 can identify the targeted conditions and take necessary measures to refresh the data without examining the remaining groupings. Moreover, the adapted management mechanism 150 can allow the preloaded data 136 to be stored without violating UFS requirements and without being limited to SLC writes as described above. Details regarding the adapted management mechanism 150 are further described below.

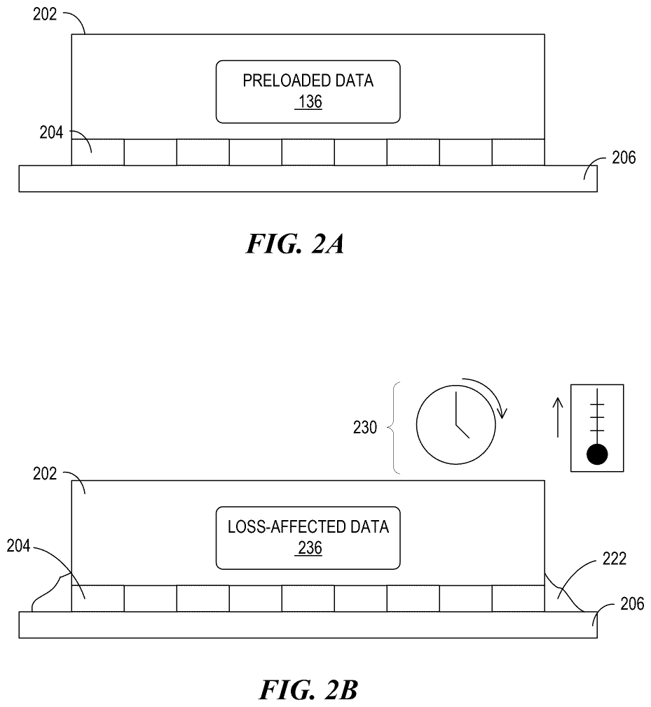

FIG. 2A and FIG. 2B illustrate manufacturing steps in accordance with an embodiment of the present technology. FIG. 2A can illustrate the storage of the preloaded data 136 into a storage device 202 (e.g., the memory array 116 of FIG. 1 or one or more packages/dies therein). For example, the preloaded data 136 can be stored in the storage device 202 after the storage device 202 is attached to or mounted on a substrate 206 (e.g., a system substrate, such as a printed circuit board (PCB)) using interconnects 204.

FIG. 2B can illustrate a manufacturing process following the storage of the preloaded data 136. For example, the manufacturing process can include applying an underfill 222 (e.g., epoxy or resin-type material) between the storage device 202, the interconnects 204, and/or the substrate 206. Alternatively, the manufacturing process can include reflowing the interconnects 204 to mount the storage device 202 (having the preloaded data 136 stored thereon) on the substrate 206.

The manufacturing process can expose the storage device 202 and the preloaded data 136 to one or more charge loss conditions 230, such as elevated temperatures or prolonged durations without power to the storage device 202 (e.g., a non-volatile memory). Accordingly, the charge loss conditions 230 can alter or deplete the stored charges, thereby potentially or likely changing the preloaded data 136 to loss-affected data 236 (e.g., reduced or shifted charges that may correspond to altered bit values).

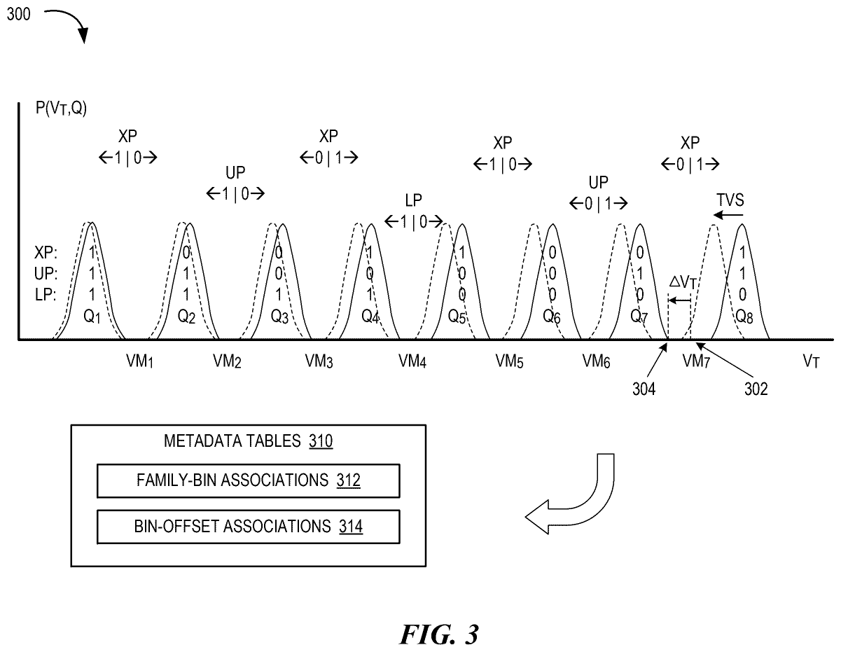

To further describe the shift from the preloaded data 136 to the loss-affected data 236 due to the charge loss conditions, FIG. 3 illustrates voltage shifts that may occur in storage devices. For the illustrated example, FIG. 3 shows temporal voltage shift (TVS) of a TLC capable of storing three bits of data by programming the memory cell into eight charge states Qₖ that differ by the amount of charge on the cell's floating gate. The distributions of threshold voltages P(V_{T}, Qₖ) are separated with 7 valley margins VMₙ. The cell programmed into k-th charge state (Qₖ) can store a particular combination of 3 bits. For example, the charge state Qₖ can store the binary combination ‘101’, as depicted. This charge state Qₖ can be determined during a readout operation by detecting that a control gate voltage V_{CG} within the valley margin VMₖ is sufficient to open the cell to the source-drain current whereas a control gate voltage within the preceding valley margin VMₖ₋₁ is not. A memory cell can be configured to store N=1 bits (SLC), N=2 bits (MLC), N=3 bits (TLC), N=4 bits (QLC), and so on, depending on how many distributions can be fit (and interspersed with adequate-size valley margins) within the working range of the control gate voltages. Even though FIG. 3 depicts a TLC, the operations described in the present disclosure can be applied to any N-bit memory cells.

Memory cells are typically joined by wordlines (e.g., conducting lines electrically connected to the cells' control gates) and programmed together as memory pages (e.g., 16 KB or 32 KB pages) in one setting, such as by selecting consecutive bitlines connected to the cells' source and drain electrodes. After three programming passes, memory cells corresponding to a wordline of a TLC can store up to three pages: lower page (LP), upper page (UP), and extra page (XP). For example, upon the first programming pass, the cell can be driven to one of the charge states Q₁, Q₂, Q₃, Q₄ (corresponding to LP bit value 1, as shown in FIG. 2) or one of the charge states Q₅, Q₆, Q₇, Q₈ (corresponding to LP bit value 0). Upon the second path, when the UP is programmed into the same wordline, the charge state of the memory cell can be adjusted so that the range of possible locations of the cell's threshold voltage is further narrowed. For example, a cell that is in one of the charge states Q₁, Q₂, Q₃, Q₄ (LP bit value 1) can be driven to just one of the two states Q₁ or Q₂ (corresponding to UP bit value 1) or to one of the two states Q₃ or Q₄ (corresponding to UP bit value 0). Similarly, upon the third programming path, the charge state of the memory cell can be fine-tuned even more. For example, a cell that is in the logic state ‘10’ (i.e., UP bit stores value 1 and LP bit stores value 0) and in one of the charge states Q₇ or Q₈ can be driven to state Q₇ (corresponding to XP bit value 0) or to state Q₈ (corresponding to XP bit value 1). Conversely, during a read operation, the memory controller can determine that the applied control gate voltage V_{CG} within the sixth valley margin VM₆ is not insufficient to open the cell to the source-drain electric current whereas the control gate voltage within the seventh valley margin VM₇ is sufficient to open the open the cell. Hence, the memory controller 115 can determine that the cell is in the charge state Q₇ corresponding to the logic state ‘010’ (i.e., XP: 0, UP: 1, LP: 0).

The distributions of threshold voltages depicted with solid lines in FIG. 3 are distributions that the memory cells have immediately after programming. With the passage of time, as a result of a slow charge loss, the distributions shift (typically, towards lower values of V_{T}), as shown by the shifted valleys indicated with dashed lines. As a result, the threshold voltages of various memory cells are shifted by certain values ΔV_{T} that can depend on the time elapsed since programming, environmental conditions (e.g., ambient temperature), and so on. For example, the solid line can correspond to the preloaded data 136 of FIG. 1, and the dashed lines can correspond to the loss-affected data 236 of FIG. 2. Moreover, the shift can be caused by the charge loss conditions 230 of FIG. 2, such as manufacturing processes (e.g., underfill flow) and/or the time between manufacturing and first power on event.

For optimal read operations, the controller can, therefore, adjust the base read levels with the corresponding offsets V_{R}→V_{R}+ΔV, which are the same (or approximately the same) as the temporal voltage shifts. In one embodiment, the offsets can be determined (or estimated) using the background scan 142 of FIG. 1 as the difference between the center of the valley margin (such as the center 302 of VM₇) immediately after programming and the center of the same—but shifted-valley margin (such as the new center) at some later instance of time. As depicted in FIG. 3, TVS of different distributions (valleys) and valley margins can differ from each other. In a typical scenario depicted in FIG. 3, TVS is greater for larger charges Q and smaller for lesser charges.

As shown in FIG. 3, the TVS in a memory device is a continuous process. In some embodiments, however, an adequate accuracy of voltage offsets can be achieved using a discrete set of bins and, accordingly, a discrete set of voltage offsets ΔV. In such embodiments, TVS phenomenon can be addressed with setting up a number of discrete bins, e.g., five, eight, twenty, etc., associated with various memory partitions. The bin-related data can be stored in metadata tables 310 (e.g., data construct in the data management mechanism 140 of FIG. 1). The associations of various memory partitions (grouped into families, as described in more detail below) with bins can be stored in family-bin associations 212 (e.g., the bin assignments 144 of FIG. 1); the family-bin associations can dynamically change with the passage of time. For example, as the memory cells continue to lose charge with time, the respective memory partitions (grouped into families) can be moved, in a consecutive fashion, from junior bins to more senior bins having larger voltage offsets.

Bin-offset associations 314 can also be stored in the metadata tables 310. In some embodiments, the bin-offset associations 314 can be static whereas the family-bin associations 312 can be adjusted (based on calibration of the memory partitions) to account for the actual charge loss by the memory cells of the respective partitions. In some embodiments, the family-bin associations 312 can store logical addresses of the memory partitions, such as LBA of the respective blocks, while associations of LBAs with respective physical block addresses (PBA) can be stored outside the metadata tables 310, e.g., in memory translations tables stored separately in the local memory or one of the memory devices. In some embodiments, however, family-bin associations 312 can additionally include LBA-to-PBA translations or store direct PBA-to-bin associations. As schematically depicted with a curved arrow in FIG. 3, the number of bins, the bin-offset associations 314, the partition bin associations can be based upon calibration of the memory device (or similar types of memory devices, e.g., during design and manufacturing) for maximizing performance and minimizing read errors during read operations.

The threshold voltage offset depends on the time after program (TAP). TAP is the time since a cell has been written and is the primary driver of TVS. TAP may be estimated (e.g., inference from a data state metric), or directly measured (e.g., from a controller clock). A cell, block, page, block family, etc. is young (or, comparatively, younger) if it has a (relatively) small TAP and is old (or, comparatively, older) if it has a (relatively) large TAP. A time slice is a duration between two TAP points during which a measurement may be made (e.g., perform reference calibration from 8 to 12 minutes after program). A time slice may be referenced by its center point (e.g., 10 minutes).

Blocks of the memory device are grouped into block families, such that each block family includes one or more blocks that have been programmed within a specified time window and possibly a specified temperature window. As noted herein above, since the time elapsed after programming and temperature are the main factors affecting the temporal voltage shift, all blocks and/or partitions within a single block family are presumed to exhibit similar distributions of threshold voltages in memory cells, and thus would require the same voltage offsets for read operations.

Block families can be created asynchronously with respect to block programming events. In an illustrative example, the memory controller can create a new block family whenever a specified period of time (e.g., a predetermined number of minutes) has elapsed since creation of the last block family or whenever the reference temperature of memory cells, which is updated at specified time intervals, has changed by more than a specified threshold value since creation of the current block family.

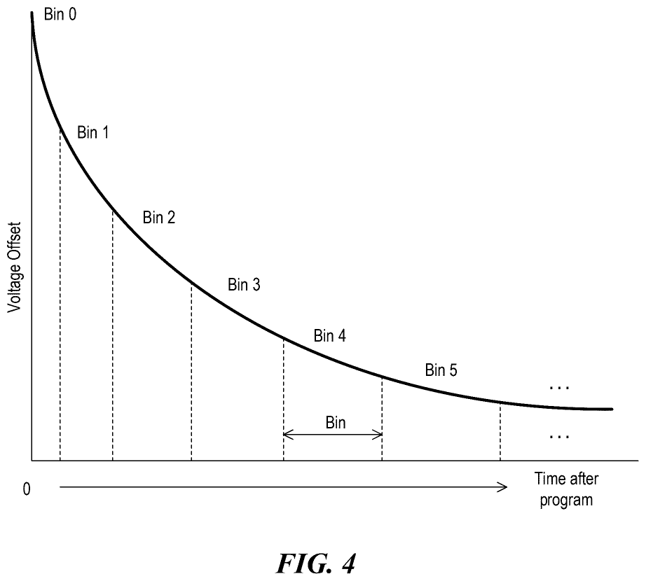

A newly created block family can be associated with bin 0. Then, the memory subsystem controller can periodically perform a calibration process in order to associate each die of every block family with one of the predefines threshold voltage offset bins (bins 0-9 in the illustrative example of FIG. 4), which is in turn associated with the voltage offset to be applied for read operations. The associations of blocks with block families and block families and dies with threshold voltage offset bins can be stored in respective metadata tables maintained by the memory sub-system controller.

The voltage distributions change in time due to the slow charge loss (SCL), which results in drifting values of the threshold voltage levels. In various embodiments of the present disclosure, the temporal voltage shift is selectively tracked for programmed blocks grouped by block families, and appropriate voltage offsets, which are based on block affiliation with a certain block family, are applied to the base read levels in order to perform read operations.

FIG. 4 illustrates example adjustments to account for the voltage shifts in accordance with an embodiment of the present technology. FIG. 4 shows a set of predefined threshold voltage offset bins (bin 0 to bin 9). As illustrated by FIG. 4, the threshold voltage offset graph 300 can be subdivided into multiple threshold voltage offset bins, such that each bin corresponds to a predetermined range of threshold voltage offsets. While the illustrative example of FIG. 4 defines ten bins (0-9), in other implementations, various other numbers of bins can be employed (e.g., 64 bins). Based on a periodically performed management process, the memory controller can associate each die of every block family with a threshold voltage offset bin (via, e.g., the bin assignments 144 of FIG. 1), which defines a set of threshold voltage offsets to be applied to the base voltage read level in order to perform read operations.

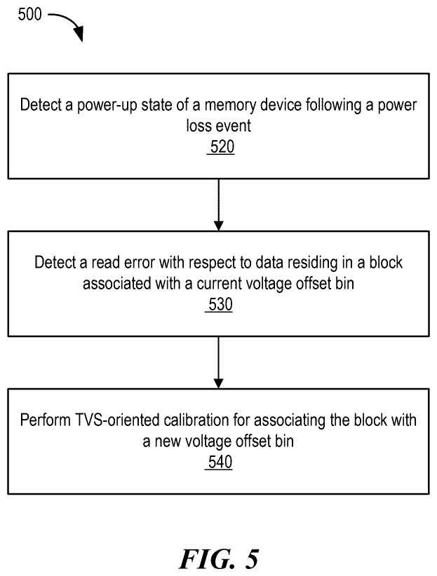

FIG. 5 is a flow diagram illustrating an example method 500 of operating an apparatus to adjust for the voltage shifts in accordance with an embodiment of the present technology. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 can correspond to the processor 122 of FIG. 1 implementing the data management mechanism 140 of FIG. 1, such as during targeted operation after deployment of the memory system 102 of FIG. 1. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At block 520, the memory system 102 can detect a power-up state thereof following a power loss event. Memory blocks may be associated with respective voltage offset bins based on statistical analysis of test data obtained from test devices mimicking the memory device. The test data can include read error data when read operations are performed in similar environmental and operational conditions as the real memory device is likely to experience. As described above, during a power loss event, all previously stored associations of memory blocks with specific voltage offset bins may be lost, and the memory device may need to be recalibrated (e.g., by initiating a re-synchronization operation) to correct and/or avoid read errors. The read errors may be associated with host-initiated read operations or system-initiated scanning operations.

At block 530, the memory system 102 can detect a read error with respect to data residing in a block of the memory device. As described above, the block is initially associated with a current voltage offset bin based on statistical analysis of test data. In certain embodiments, if two or more read errors are detected with respect to multiple blocks, the memory system 102 can select a block associated with a voltage offset bin corresponding to a lowest voltage offset value. In other words, priority is given to relatively older bins over relatively younger bins, as the likelihood of TVS being the dominant voltage distortion mechanism in the older bins is much higher than that in the relatively younger bins. Note that detecting the read error can be performed in response to performing a host-initiated read operation or during the background scan 142 of FIG. 1.

At block 540, responsive to error detection, the memory system 102 can perform TVS-oriented adjustments for associating the block with a new voltage offset bin. For example, the memory system 102 can use the data management mechanism 140 update the bin assignment 144 of FIG. 1. For the background scan 142, the memory system 102 can continue scanning and adjusting the bin assignments 144 until the iterative process completes the management of a targeted or a full set of the blocks or the data management groupings 134 of FIG. 1.

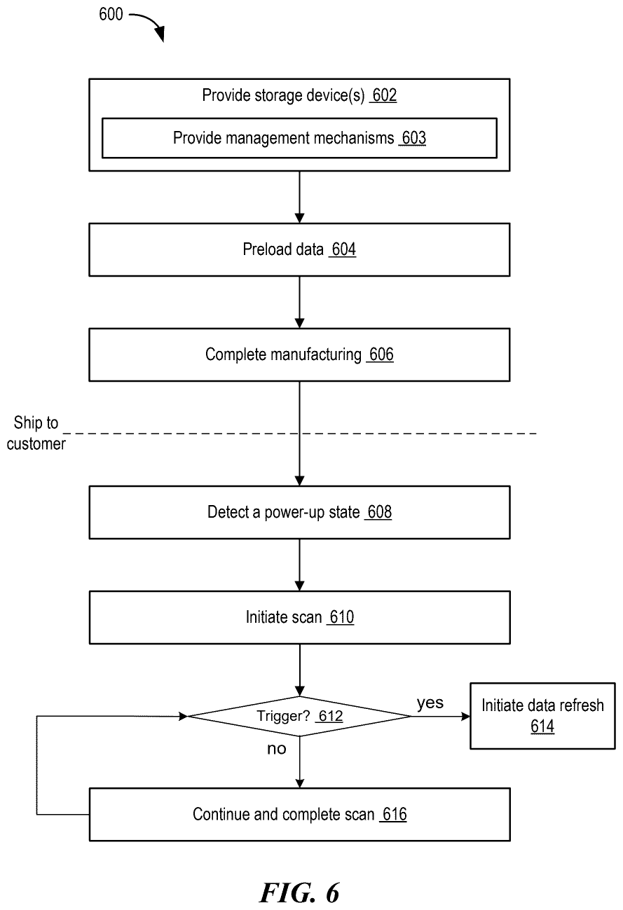

FIG. 6 is a flow diagram illustrating an example method 600 of manufacturing/operating an apparatus to adapt the adjustment in initializing the apparatus in accordance with an embodiment of the present technology. A first portion of the method 600 can correspond to manufacturing processes for the memory system 102 of FIG. 1 and/or the computing system 100 of FIG. 1. A second portion of the method 600 can correspond to operations performed by processing logic following the manufacturing process. The second portion of the method 600 can be performed by hardware (e.g., processing device, circuitry, dedicated logic, programmable logic, microcode, hardware of a device, integrated circuit, etc.), software (e.g., instructions run or executed on a processing device), or a combination thereof. In some embodiments, the second portion of the method 600 can correspond to the processor 122 of FIG. 1 implementing the adapted management mechanism 150 of FIG. 1, such as during targeted operation after deployment of the memory system 102. Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At block 602, storage devices (e.g., the storage devices 202 of FIG. 2A) may be provided. For example, the manufacturer can be provided with the memory array 116 of FIG. 1 or one or more components (e.g., the chips or packages). Providing the storage devices can include providing management mechanisms, such as the data management mechanism 140 of FIG. 1 and/or the adapted management mechanism 150, as illustrated in block 603. For example, the manufacturer can be provided with the memory array 116 and/or the memory controller 114 of FIG. 1 including logic, software, firmware, or the like having the management mechanisms. In some embodiments, the provided storage devices can be mounted to a system substrate (e.g., PCB).

At block 604, the storage devices can be preloaded with data (e.g., the preloaded data 136 of FIG. 1). For example, the manufacturer can load the OS or an image thereof to the storage device that has been attached to the system substrate.

At block 606, the manufacturing process can be completed. In other words, the manufacturer can use the storage devices to complete manufacturing the memory system 102 of FIG. 1 and/or the computing system 100 of FIG. 1 (e.g., a user device). In completing the manufacturing process, the storage devices (having the preloaded data 136 stored therein) can be exposed to charge loss conditions 230 of FIG. 2. For example, the storage devices may be subjected to elevated temperatures for flowing the underfill 222 of FIG. 2.

In some instances, the storage devices can be subjected to other charge loss conditions 230. For example, the computing system 100 can be stored in a warehouse and/or a store before the user purchases and uses the computing system 100. Given the packaged state of the computing system 100, the memory system 102 can remain in an unpowered state (e.g., a low battery charge level and/or a power-off mode) for a prolonged or an unpredictable duration.

At block 608, the memory system 102 can detect a power-up state. The memory system 102 can detect the power-up state similarly as described above with respect to block 520 of FIG. 5. For example, the memory system 102 can detect the power-up state through a power-cycling or a booting process. In some embodiments, the memory system 102 can detect a targeted power-up condition, such as the adapted management trigger 151 of FIG. 1. For example, the memory system 102 can detect the targeted power-up condition using a tracked status, a tracked power-off duration, or the like described above.

At block 610, the memory system 102 can initiate a scan, such as the background scan 142 of FIG. 1. In some embodiments, the memory system 102 can initiate the scan as a part of the adapted management mechanism 150 of FIG. 1. The memory system 102 can be configured to initiate the adapted management mechanism 150 as a part of the power-up process and/or when the targeted power-up conditions have been met. The memory system 102 can implement the background scan 142 on the memory blocks 132 of FIG. 1 or data management groupings 134 of FIG. 1 (e.g., block families, super blocks, etc.). The memory system 102 can scan according to a predetermined rule, such as for reviewing the blocks/groupings according to storage duration (e.g., oldest/newest blocks/groupings first). Effectively, the memory system 102 can implement the background scan 142 to estimate the charge loss associated with the preloaded data 136 of FIG. 1.

At decision block 612, the memory system 102 can determine whether the scanning results meet the conditions for triggering the data refresh mechanism 160 of FIG. 1. For example, the memory system 102 can track the adjustment progress 152 of FIG. 1 (e.g., the PEC) during the background scan 142 and compare to the refresh trigger condition 154 of FIG. 1. When the adjustment progress 152 meets the refresh trigger condition 154, the memory system 102 can initiate the data refresh process as illustrated in block 614. In other words, the memory system 102 can use the adjustment progress 152 and the refresh trigger condition 154 to estimate the FoB condition. In response to estimating the FoB or other targeted condition (e.g., excessive memory loss), the memory system 102 can stop the background scan 142 and implement the data refresh mechanism 160 instead of completing the background scan 142.

Otherwise, when the adjustment progress 152 remains outside of the refresh trigger condition 154, the memory system 102 can continue to implement the background scan 142. Along with implementing the background scan 142, the memory system 102 can adjust the bin assignments 144 of FIG. 1. The memory system 102 can continue to track the background scan 142 and compare to the refresh trigger condition 154 until the background scan 142 reaches a targeted marker (e.g., 25%, 50%, or other similar number of groupings).

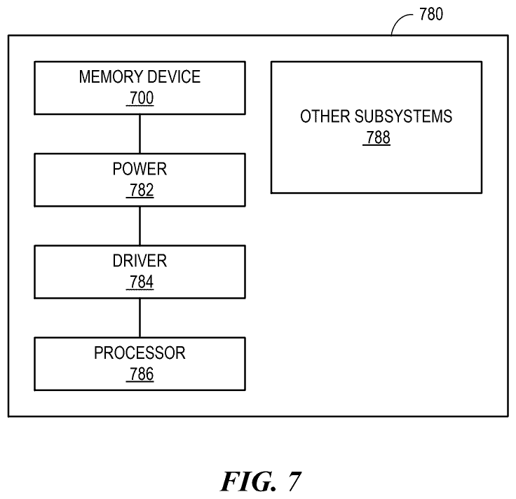

FIG. 7 is a schematic view of a system that includes an apparatus in accordance with embodiments of the present technology. Any one of the foregoing apparatuses (e.g., memory devices) described above with reference to FIGS. 1-6 can be incorporated into any of a myriad of larger and/or more complex systems, a representative example of which is system 780 shown schematically in FIG. 7. The system 780 can include a memory device 700, a power source 782, a driver 784, a processor 786, and/or other subsystems or components 788. The memory device 700 can include features generally similar to those of the apparatus described above with reference to one or more of the FIGS. 1-7, and can therefore include various features for performing a direct read request from a host device. The resulting system 780 can perform any of a wide variety of functions, such as memory storage, data processing, and/or other suitable functions. Accordingly, representative systems 780 can include, without limitation, hand-held devices (e.g., mobile phones, tablets, digital readers, and digital audio players), computers, vehicles, appliances and other products. Components of the system 780 may be housed in a single unit or distributed over multiple, interconnected units (e.g., through a communications network). The components of the system 780 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or performance occurring during operation, usage, or deployment of a corresponding device, system or embodiment, and after or while running manufacturer's or third-party firmware. The dynamically occurring processes, functions, actions or performances can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

I/We claim:

1. A memory device, comprising:
a memory array including memory cells configured to store charges representative of stored data, wherein the memory array includes preloaded data; and
a logic circuit coupled to the memory array and configured to:
implement a background scan configured to estimate a charge loss associated with the preloaded data;
track an adjustment progress during the background scan, wherein the adjustment progress quantitatively represents the charge loss; and
when the adjustment progress meets a refresh trigger condition, stop the background scan and implement a data refresh mechanism that restores the preloaded data.

2. The memory device of claim 1, wherein the logic circuit is configured to:
implement a data management mechanism that, during deployed operation of the memory device, (1) implements the background scan for a set of data management groupings and (2) determines an offset for a read level voltage according to the background scan for one or more groupings in the set of data management groupings;
implement the background scan of the data management mechanism to identify a targeted charge loss condition as represented by the refresh trigger condition, wherein the targeted charge loss condition is a unique condition within the deployed operation;
when the adjustment progress meets the refresh trigger condition, deviate from the data management mechanism by stopping the background scan; and
implement the data refresh mechanism after stopping the background scan.

3. The memory device of claim 2, wherein:
the memory cells are grouped into memory blocks;
the set of data management groupings include groupings of the memory blocks into block families according to estimated charge loss conditions; and
the logic circuit is configured to determine the offset for the read level voltage for one or more of the block families until the targeted charge loss condition is identified.

4. The memory device of claim 2, wherein the adjustment progress includes a count of program-erase operation occurring during and in response to the background scan.

5. The memory device of claim 4, wherein the refresh trigger condition is greater than five, less than 20, or both for implementations of the program-erase operation.

6. The memory device of claim 5, wherein the refresh trigger condition is for identifying the targeted charge loss condition associated with a first-time power up event for the memory device for a fresh-out-of-box (FoB) condition.

7. The memory device of claim 1, wherein:
the memory device comprises a mobile electronic device that includes (1) a substrate having the memory array mounted thereon and (2) an underfill disposed between the substrate and the memory array; and
the logic circuit is configured to adjust for the charge loss that corresponds to (1) a high temperature environment associated with the underfill, (2) a storage duration of the mobile electronic device, or a combination thereof.

8. The memory device of claim 7, wherein:
the memory cells include persistent storage cells; and
the preloaded data includes an operating system, or an image thereof, for the mobile electronic device stored in the persistent storage cells before the high temperature environment.

9. The memory device of claim 8, wherein the memory device is a NAND memory device.

10. The memory device of claim 7, wherein the logic circuit is configured to manage the preloaded data during a device initialization condition by:
implementing the background scan that is configured to scan a set of data management groupings during operation after a targeted charge loss condition as represented by the refresh trigger condition; and
implementing the data refresh mechanism without completing the background scan according to the adjustment progress to reduce a duration for managing the preloaded data.

11. The memory device of claim 7, wherein the mobile electronic device is a mobile phone, a tablet computer, or a smart phone.

12. A method of manufacturing a memory device that includes memory cells configured to store charges representative of stored data, the method comprising:
mounting the memory device over a substrate;
storing preloaded data in the memory device, wherein the preloaded data includes an operating system or an image thereof; and
flowing underfill between the memory device and the substrate after storing the preloaded data, wherein flowing the underfill includes increasing ambient temperatures to a level that increases charge loss in the memory array;
wherein the memory device includes a logic circuit configured to:
implement an iterative process that (1) scans a set of data management groupings of the memory cells to estimate charge losses therein and (2) adjusts read level offsets for one or more groupings in the set thereof according to a corresponding charge loss;
track an adjustment progress while implementing the iterative process;
determine that the adjustment progress reached a refresh trigger condition;
stop the iterative process without completing scan of the set of data management groupings when the adjustment progress reaches the refresh trigger condition; and
implement a data refresh mechanism that refreshes data stored on the memory device when the adjustment progress reaches a refresh trigger condition.

13. The method of claim 12, wherein the logic circuit is configured to estimate a fresh-out-of-box (FoB) condition based on determining that the adjustment progress reached the refresh trigger condition while implementing the iterative process, wherein the FoB condition represents a first power on by a user after purchase.

14. The method of claim 13, wherein the logic circuit is configured to response to estimating the FoB condition by implementing the data refresh mechanism to restore the operating system or the image thereof that was negatively affected by the charge loss caused by the underfill flow.

15. A method of operating a memory device that includes memory cells configured to store charges representative of stored data, the method comprising:
detecting a power on state;
implementing an iterative process that (1) scans a set of data management groupings of the memory cells to estimate charge losses therein and (2) adjusts read level offsets for one or more groupings in the set thereof according to a corresponding charge loss;
tracking an adjustment progress while implementing the iterative process;
determining that the adjustment progress reached a refresh trigger condition;
stopping the iterative process without completing scan of the set of data management groupings when the adjustment progress reaches the refresh trigger condition; and
implementing a data refresh mechanism that refreshes data stored on the memory device when the adjustment progress reaches a refresh trigger condition.

16. An electronic apparatus, comprising:
a printed circuit board (PCB); and
a memory system mounted on the PCB, the memory system including:
a memory array including memory cells configured to store charges representative of stored data, wherein the memory cells include preloaded data that was stored therein during manufacturing of the memory system; and
a controller coupled to the memory array and configured to:
implement a management mechanism that (1) scans a subset of the memory cells to estimate charge losses therein and (2) adjusts read level offsets for one or more groupings of the memory cells according to a corresponding charge loss;
track an adjustment progress while implementing the management mechanism;
determine that the adjustment progress reached a refresh trigger condition;
stop the management mechanism when the adjustment progress reaches the refresh trigger condition; and
implement a data refresh mechanism that refreshes data stored on the m memory array when the adjustment progress reaches a refresh trigger condition.

17. The electronic apparatus of claim 16, wherein the controller is configured to:
use the management mechanism to estimate a fresh-out-of-box (FoB) condition based determining that the adjustment progress reached the refresh trigger condition, wherein the logic circuit is configured to complete implementation of the management mechanism during operation of the electronic apparatus after the FoB condition; and
implement the refresh mechanism instead of completing the management mechanism to refresh the preloaded data in response to estimating the FoB condition.

18. The electronic apparatus of claim 17, wherein the controller is configured to implement the data refresh mechanism to restore initial states of stored charges for the preload data instead of adjusting the read level offsets to account for the charge losses associated with the FoB condition.

19. The electronic apparatus of claim 16, wherein the controller is configured to track the adjustment progress by tracking a number of times a program-erase operation occurs during implementation of the management mechanism.

20. The electronic apparatus of claim 16, wherein:
the electronic apparatus is a mobile computing device; and
the memory system includes NAND memory cells.
